(19) United States
(12) Patent Application Publication
(10) Pub. No.: US 2016/0294416 A1
(43) Pub. Date: Oct. 6, 2016

(54) DECODING METHOD OF LOW DENSITY PARITY CHECK CODE AND INFORMATION STORING METHOD IN THE DECODING METHOD

(71) Applicant: NATIONAL TSING HUA UNIVERSITY, HSINCHU CITY (TW)

(72) Inventors: CHIEH-SHEN HSIEH, HSINCHU CITY (TW); HUANG-CHANG LEE, HSINCHU CITY (TW); YEONG-LUH UENG, HSINCHU CITY (TW)

(21) Appl. No.: 14/790,043

(22) Filed: Jul. 2, 2015

(30) Foreign Application Priority Data
Apr. 2, 2015 (TW) 104110867

(51) Int. Cl. H03M 13/11

(52) U.S. Cl. CPC H03M 13/1128; H03M 13/1108; H03M 13/1117

(57) ABSTRACT

A decoding method of a LDPC comprises following steps. A first predetermined number of iterations of a messages-passing decoding algorithm are applied to a received signal vector, so as to attempt to decode a transmitted (or stored) codeword. Whether the decoding result converges to a valid codeword is determined by observing whether the decoding result makes all check nodes satisfied or not. When the decoding result does not converge to a valid codeword, the value of at least one of the variable nodes neighboring to one of the un-satisfied check node is be adjusted to a non-zero value, wherein the selected variable node is included in a trapping set. Then, a second predetermined number of iterations of the messages-passing decoding algorithm are applied to the updated decoding result to generate another one decoding result, and whether the other one decoding result converges to a valid codeword is checked.

### BACKGROUND

1. Technical Field

The instant disclosure relates to a decoding method of a Low Density Parity Check (LDPC) code; more particularly, to a decoding method of LDPC code which can reduce the necessary storage space and an information storing method using in the decoding method.

2. Description of Related Art

The LDPC code performs excellently in the water-fall region, and even can have a channel capacity approaching Shannon limitation. Since the LDPC code has the outstanding performance, a large number of standards (such as DVB-S2/T2/C2/H, IEEE802.3an, IEEE802.16e, IEEE802.11ac) adopt the LDPC code, and even the storage apparatuses utilize the LDPC code for error correction.

However, the error-flooring phenomenon limits the LDPC codes to be applied to some communication systems and storage apparatuses which require the ultra-low bit error rate. The error-flooring phenomenon is caused by that the trapping sets formed by some specific structures of Tanner graph associated with the parity check matrix H make the message-passing decoder fail to decode the correct codeword.

To put it concretely, when the LDPC code is decoded, Tanner graph can be utilized to present the parity check matrix H, wherein Tanner graph has a plurality of variable nodes and a plurality of check nodes therein. Iterations of the messages-passing decoding algorithm are applied to each of the variable nodes and its one or more neighboring check nodes to calculate the probability of the variable node being 0 or 1, so as to decode the codeword. Unfortunately, some variable nodes and check nodes in Tanner graph may form the trapping sets. In the trapping sets, all variable nodes are in error, but most of the check nodes are mis-satisfied and cannot provide enough decoding messages to correctly decode the received vector.

Currently, in one proposed solution, all location information of the variable nodes and the check nodes associated with the trapping sets is recorded in a table. After the iterations have been performed, if the decoding result cannot converge to a valid codeword, the table is utilized to check whether the errors exist in the recorded check nodes, and the check nodes with the errors can be named unsatisfied check nodes. Next, according to the location information recorded in the table, values of all the variable nodes neighboring to the unsatisfied check nodes are flipped (i.e. changed to be 1 from 0, or 0 from 1), so as to update the decoding result. Next, after the values of all the variable nodes neighboring to the unsatisfied check nodes are flipped, iterations of the messages-passing decoding algorithm are applied to the updated decoding result, so as to attempt to decode the valid codeword.

Though the above proposed solution can fast decode the codeword, the location information of all the variable nodes and the check nodes in the trapping sets should be recorded in the table. Thus, the large storage space is needed, and the hardware cost is increased. In addition, if the location information of the variable nodes and the check nodes in one trapping set is not recorded, and the errors exist in the check nodes of the trapping set, the propose solution may not correct errors successfully.

Furthermore, other one proposed solution does not record the location information of the variable nodes and the check nodes in the trapping sets, and when that the unsatisfied check nodes exist is checked, the other one proposed solution arbitrarily selects one of the variable nodes neighboring to each unsatisfied check node, and flips the values of the selected variable nodes, so as to update the decoding result. Then, the iterations of the messages-passing decoding algorithm are applied to the updated decoding result, so as to attempt to decode the valid codeword. If the decoding result still cannot converge to the valid codeword, the other one proposed solution selects other one of the variable nodes neighboring to each unsatisfied check node, and flips the values of the selected variable nodes, so as to update the decoding result. The other one proposed solution repeatedly selects one of the one of the variable nodes neighboring to each unsatisfied check node and flips the value of the selected variable node until the decoding result converges to the valid codeword or the number of the iterations reaches a predetermined number.

The above other one proposed solution does not record the location information of the variable nodes and check nodes in the trapping sets, thus the storage space is reduced much, and it has flexibility to correct more errors. However, the above other one proposed solution needs longer decoding time.

### SUMMARY

An exemplary embodiment of the present disclosure provides a decoding method of a LDPC code, executed in an electronic apparatus, comprising following steps. At step A, a first predetermined number of iterations of a messages-passing decoding algorithm are applied to a received signal vector, so as to obtain as decoding result. At step B, whether the decoding result converges to a valid codeword is determined. At step C, if the decoding result does not converge to the valid codeword, at least one of steps C1 and C2 is executed. At the step C1, value of at least one of variable nodes neighboring to at least one unsatisfied check node is adjusted to a non-zero value, so as to update decoding result. At the step C2, the values of the variable node corresponding to the unsatisfied check nodes of a trapping set recorded in a first table are flipped, so as to update the decoding result, wherein the first table merely records location information of the unsatisfied check node in the trapping set and location information of merely one of the variable nodes neighboring to the unsatisfied check node in the trapping set. At step D, a second predetermined number of the iterations of the messages-passing decoding algorithm are applied to the updated decoding result, so as to obtain a new decoding result.

An exemplary embodiment of the present disclosure provides an information storing method using in a decoding method of a LDPC code, executed in an electronic apparatus, adopted for decoding a structural LDPC code, comprising steps as follows. At step A, location information of at least one variable node neighboring to at least one unsatisfied check node in an isomorphism trapping set is recorded. At step B, a base matrix for generating a parity check matrix is recorded, wherein the other isomorphism trapping sets can be generated by the base matrix and the recorded isomorphism trapping set.

To sum up, the decoding methods of the LDPC code in the exemplary embodiments of the present disclosure can decrease the storage space and hardware cost. Furthermore, the information storing method used in the decoding method of the LDPC code in the exemplary embodiment of the present disclosure utilizes isomorphism of the structural LDPC code to reduce the necessary storage space for recording information used to resists the error-flooring phenomenon.

In order to further understand the techniques, means and effects the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a schematic diagram of the (4, 2) trapping set according to an exemplary embodiment of the present disclosure.

FIG. 2 is a flow chart of a decoding method of a LDPC code according to an exemplary embodiment of the present disclosure.

FIG. 3 is a flow chart of a decoding method of a LDPC code according to another one exemplary embodiment of the present disclosure.

FIG. 4 is a flow chart of a decoding method of a LDPC code according to another one exemplary embodiment of the present disclosure.

FIG. 5 is a flow chart of a decoding method of a LDPC code according to another one exemplary embodiment of the present disclosure.

FIG. 6-1 and FIG. 6-2 are a flow chart of a decoding method of a LDPC code according to another one exemplary embodiment of the present disclosure.

FIG. 7 is a schematic diagram of a parity check matrix and a base matrix of a quasi-cyclic LDPC code according to an exemplary embodiment of the present disclosure.

FIG. 8 is a flow chart of an information storing method used in a decoding method of a LDPC code according to an exemplary embodiment of the present disclosure.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or similar parts.

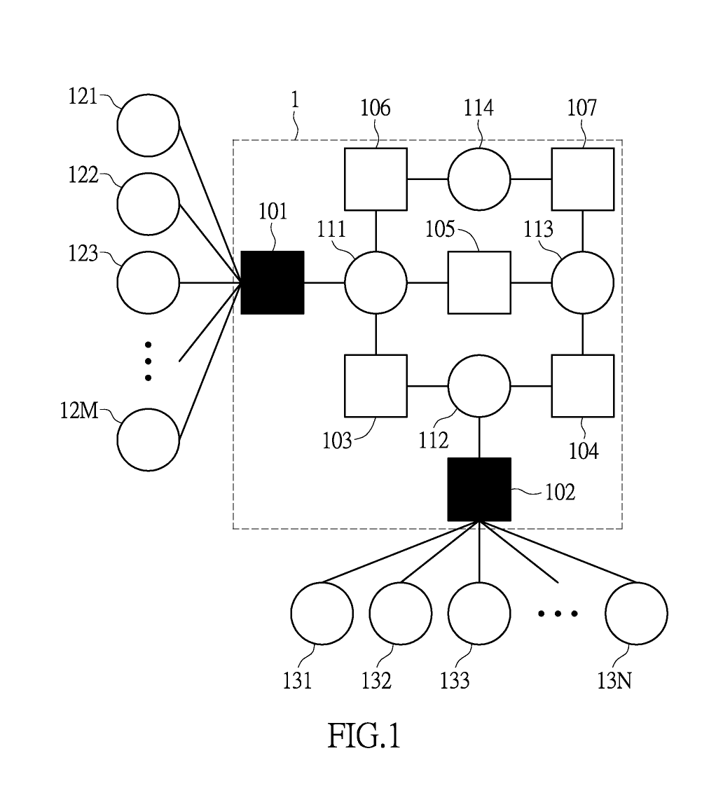

Referring to FIG. 1, FIG. 1 is a schematic diagram of the (4, 2) trapping set according to an exemplary embodiment of the present disclosure. The (4, 2) trapping set 1 is formed by a plurality of check nodes 101 through 107 and a plurality of variable nodes 111 through 114, wherein the notation (4, 2) means the (4, 2) trapping set 1 has two unsatisfied check node 101, 102 and 4 variable nodes 111 through 114.

In FIG. 1, the unsatisfied check node 101 is connected to the variable nodes 111 and the variable nodes 121 through 12M outside the (4, 2) trapping set 1, and the unsatisfied check node 102 is connected to the variable node 112 and the variable nodes 131 through 13N outside the (4, 2) trapping set 1, wherein M and N are positive integers. The check node 103 is connected to the variable nodes 111 and 112, the check node 104 is connected to the variable nodes 112, 113, the check node 105 is connected to the variable nodes 111, 113, the check node 106 is connected to the variable nodes 111, 114, and the check node 107 is connected to the variable nodes 113, 114.

In the (4, 2) trapping set 1, the unsatisfied check nodes 101 and 102 cannot correct errors successfully. That is, the unsatisfied check nodes 101 and 102 cannot check whether their neighboring variable nodes have errors, and the messages-passing decoding algorithm cannot be utilized to correct the errors of the variable nodes neighboring to the unsatisfied check nodes 101 and 102. Thus, the (4, 2) trapping set 1 may make the LDPC code cannot be decoded correctly, and the error-flooring phenomenon is caused.

To avoid the error-flooring phenomenon without significantly increasing the storage space, exemplary embodiments of the present disclosure provide several decoding methods of the LDPC codes which can decrease storage space and hardware cost. The decoding methods of the LDPC codes can be independently used or be merged to achieve the trade-off between the reduction of error-flooring phenomenon and necessary recorded information of the trapping sets. In addition, for the quasi-cyclic LDPC code and other structural LDPC code, an exemplary embodiment of the present disclosure provides an information storing method used in the decoding method of the LDPC code, and the information storing method utilizes isomorphism of the structural LDPC code to reduce the necessary storage space for recording information used to resists the error-flooring phenomenon.

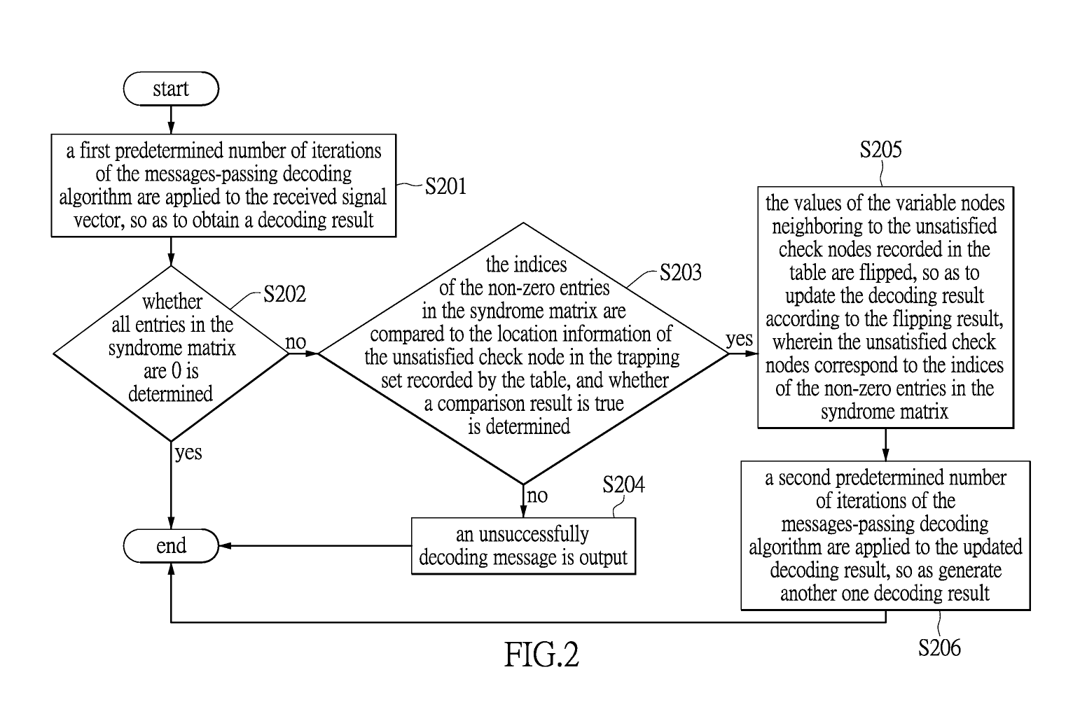

Referring to FIG. 2, FIG. 2 is a flow chart of a decoding method of a LDPC code according to an exemplary embodiment of the present disclosure. The decoding method of a LDPC code in the exemplary embodiment of FIG. 2 is executed in an electronic apparatus, such as a receiver or a memory access circuit, and the electronic apparatus has one or more circuits for achieving calculation and storage. The decoding method of a LDPC code in the exemplary embodiment of FIG. 2 still needs a table for recording information, but the location information of the variable nodes and the unsatisfied node in merely portion of the trapping sets is recorded. For each unsatisfied check node, the table records the location information of merely one variable nodes neighboring to the unsatisfied check node. The above portion of the trapping sets may be the dominant trapping sets, the trapping sets can be obtained according to simulation results, such as an importance sampling simulation result, and present disclosure is not limited thereto.

At step S201, a first predetermined number of iterations of the messages-passing decoding algorithm are applied to the received signal vector, so as to obtain a decoding result. Then, at step S202, whether all entries in the syndrome matrix are 0 is determined, such as by observing whether the decoding result makes all check nodes satisfied or not (i.e. whether the codeword of the decoding result makes the equation of parity check matrix satisfied or not) to judge whether the decoding result converges to the valid codeword, and the present disclosure is not limited thereto. If the all entries in the syndrome matrix are 0, it means the decoding result converges to the valid codeword, and the decoding result is assumed correct, thus ending the decoding method of the LDPC code. If the one of entries in the syndrome matrix is not 0, it means the decoding result cannot converge to the valid codeword, and the decoding result is assumed not correct, thus executing step S203 next.

At step S203, the indices of the non-zero entries in the syndrome matrix are compared to the location information of the unsatisfied check node in the trapping set recorded by the table, and whether a comparison result is true is determined. That is, whether the all indices of the non-zero entries in the syndrome matrix match the recorded location information of the unsatisfied check node is judged. If the comparison result is false, it means the indices of the non-zero entries in the syndrome matrix do not match the recorded location information of the unsatisfied check node, then at step S204, an unsuccessfully decoding message is output, and the decoding method of the LDPC code is ended. If the comparison result is true, it means the indices of the non-zero entries in the syndrome matrix match the recorded location information of the unsatisfied check node, and then step S205 is executed.

Next, at step S205, the values of the variable nodes neighboring to the unsatisfied check nodes recorded in the table are flipped (i.e. the signs of the values are inversed), so as to update the decoding result according to the flipping result, wherein the unsatisfied check nodes correspond to the indices of the non-zero entries in the syndrome matrix. Then, at step S206, a second predetermined number of iterations of the messages-passing decoding algorithm are applied to the updated decoding result, so as generate another one decoding result. The second predetermined number may be not the same as the first predetermined number, and the present disclosure is not limited thereto. That is, in other implementation, the first predetermined number can be the same as the second predetermined number.

Referring to both of FIG. 1 and FIG. 2, the (4, 2) trapping set 1 in FIG. 1 can be a dominant trapping set for example, and the table used by the decoding method of the LDPC code in the exemplary embodiment of FIG. 2 records the location information of the unsatisfied check nodes 101 and 102 in FIG. 1 and variable nodes 111 and 112 neighboring to the unsatisfied check nodes 101 and 102. At step S203, if the comparison result presents that the indices of the non-zero entries in the syndrome matrix correspond to the location information of the unsatisfied check nodes 101 and 102 in the (4, 2) trapping set 1 recorded in the table, then at step S205, the values of the variable nodes 111 and 112 neighboring to the unsatisfied check nodes 101 and 102 are flipped.

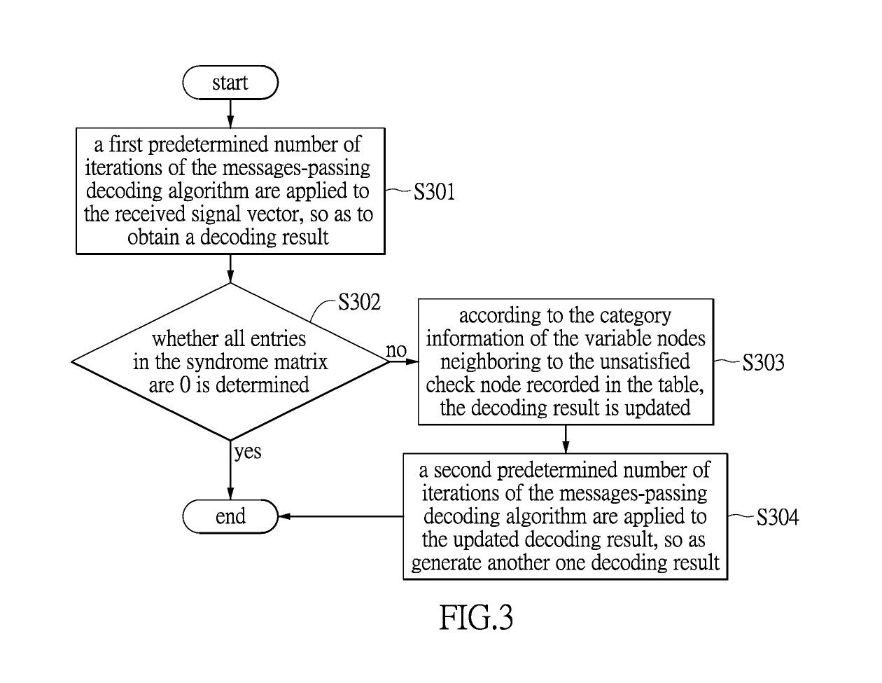

In short, the decoding method of the LDPC code in the exemplary embodiment of FIG. 2 does not need to record location information of the all check nodes 101 through 107 and the all variable nodes 111 through 114 in the (4, 2) trapping set 1 in the table, but merely record the location information of the unsatisfied check nodes 101, 102, and the variable nodes 111, 112. Thus, the decoding method of the LDPC code in the exemplary embodiment of FIG. 2 can reduce the storage space and have the fast decoding speed. Next, referring to FIG. 3, FIG. 3 is a flow chart of a decoding method of a LDPC code according to another one exemplary embodiment of the present disclosure. The decoding method of the LDPC code in the exemplary embodiment of FIG. 3 can be executed in the electronic apparatus, and the electronic apparatus has one or more circuits for achieving calculation and storage. The decoding method of the LDPC code in the exemplary embodiment of FIG. 3 still needs to use the table, but the location information of the variable nodes and the unsatisfied check nodes in the merely portion of trapping sets are recorded in the table. The above portion of the trapping sets may be the dominant trapping sets which can be obtained by a simulation result, such as an importance sampling simulation result, and present disclosure is not limited thereto.

It is noted that, for each trapping set, the location information of the all unsatisfied check nodes is recorded in the table. For each recorded unsatisfied check node, the location information and category information of the variable nodes neighboring to the unsatisfied check node is recorded, wherein the category information of the variable nodes neighboring to the unsatisfied check node can be can be obtained by a simulation result, such as an importance sampling simulation result.

In FIG. 3, steps S301, S302, S304 are respectively the same as steps S201, S202, 206, and thus the redundant descriptions are omitted. Next, at step S303, according to the category information of the variable nodes neighboring to the unsatisfied check node recorded in the table, the decoding result is updated. That is, according to the recorded category information, the values of the variable nodes neighboring to the unsatisfied check node are adjusted, so as to update the decoding result.

It is noted that, the variable nodes neighboring to the unsatisfied check node can be categorized into three groups, but the present disclosure is not limited thereto. The variable node with the first category information is categorized as the critical variable node, wherein its value variation affects the unsatisfied check node easily. The variable node with the second category information is categorized as the common variable node, wherein compared to the critical node, the value variation of the common variable node affects the unsatisfied check node less. The variable node with the third category information is categorized as the negligible variable node, wherein its value variation does not affect the unsatisfied check node almost.

The value of the variable node with the first category information can be lowered much, the value of the variable node with the second category information can be lowered little, and the value of the variable node with the third category information maintains unchanged. For example, the value of the variable node with the first category information is adjusted to a first parameter, and the value of the variable node with the second category information is adjusted to a second parameter. The first and second parameters can be obtained by a simulation result, such as an importance sampling simulation result, and present disclosure is not limited thereto.

However, the present disclosure does not limit the categorization manner. That is, the variable nodes neighboring to the unsatisfied check node can be categorized according to the actual requirements, and more than three groups can be categorized. Furthermore, the above manner for adjusting the values of the variable nodes according to the category information is also not used to limit the present disclosure, and such manner for adjusting the values of the variable nodes by multiplying the values of the variable nodes respectively with corresponding parameters according to the category information is one of several implementations.

Referring to FIG. 1 and FIG. 3, the (4, 2) trapping set 1 in FIG. 1 can be a dominant trapping set for example. The information recording in the table of the decoding method of the LDPC code of the exemplary embodiment in FIG. 2 is not the same as that of the decoding method of the LDPC code of the exemplary embodiment in FIG. 3. The table used by the decoding method of the LDPC code in the exemplary embodiment of FIG. 3 merely records the location information of the unsatisfied check nodes 101 and 102 in FIG. 1 and the variable nodes 111, 112, 121 through 12M, 131 through 13N neighboring to the unsatisfied check nodes 101 and 102. Additionally, the category information of the variable nodes 111, 112, 121 through 12M, 131 through 13N neighboring to the unsatisfied check nodes 101 and 102 is also recorded in the table.

Assuming the variable nodes 121, 112 are the critical variable nodes, the variable nodes 122, 131, 132 are the common variable nodes, and the variable nodes 122 through 12M and 133 through 13N are the negligible variable nodes, if one of the entries of the syndrome matrix at step S302 is not 0, then at step S303, the value of the variable nodes 121, 112 are adjusted to the first parameters, the values of the variable nodes 122, 131, and 132 are adjusted to the second parameters, and the values of the variable nodes 122 through 122M and 133 through 133N remain unchanged, wherein the second parameter is larger than the first parameter.

In short, the decoding method of the LDPC code of the exemplary embodiment in FIG. 3 does not need to record the location information of the all check nodes 101 through 107 and the all variable nodes 111 through 114 in the (4, 2) trapping set 1, but merely records the location information of the unsatisfied check nodes 101, 102, and the location information and the category information of the variable nodes 111, 112, 121 through 12M, 131 through 13N. Thus, the decoding method of the LDPC code of the exemplary embodiment in FIG. 3 can reduce the storage space and have the fast decoding speed.

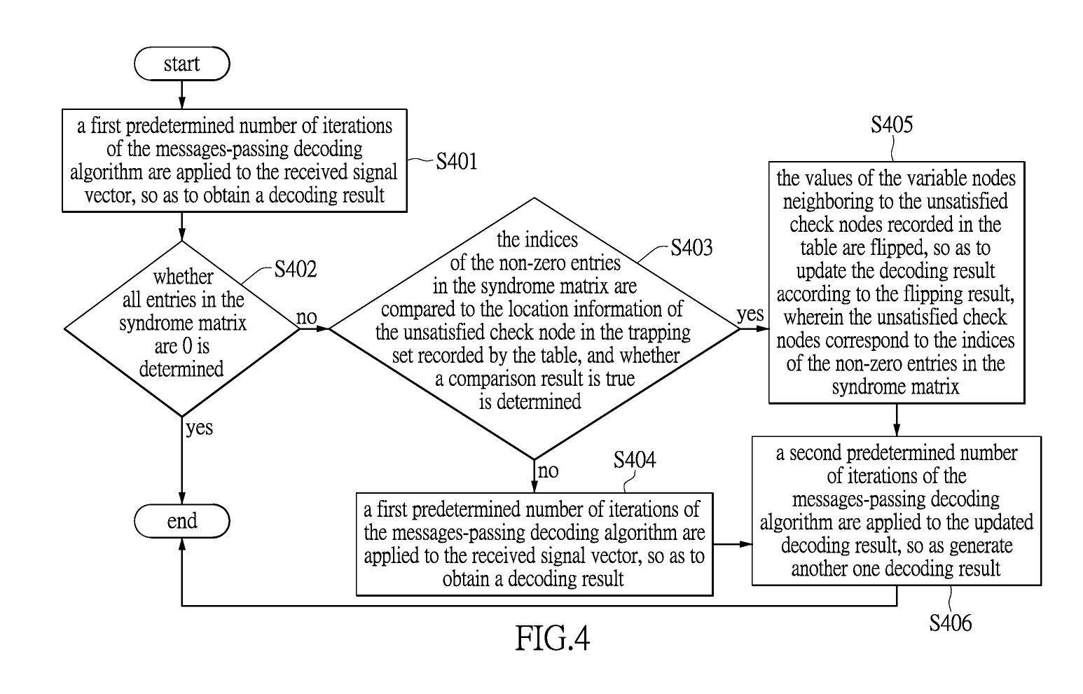

Referring to FIG. 4, FIG. 4 is a flow chart of a decoding method of a LDPC code according to another one exemplary embodiment of the present disclosure. The decoding methods of the LDPC code in the exemplary embodiments of FIG. 2 and FIG. 3 can be merged and combined, so as to increase the decoding accuracy or decoding speed. In the exemplary embodiment of FIG. 4, steps S401 through 403, S405, and S406 are respectively the same as steps S201 through 203, S205 and S206 in FIG. 2, and step S404 is the same as step S303 in FIG. 3.

In short, in the exemplary embodiment of FIG. 4, the electronic apparatus can determine use step S205 in FIG. 2 or step S303 in FIG. 3 to update the decoding result according to whether the indices of the non-zero entries match the location information of the unsatisfied check nodes.

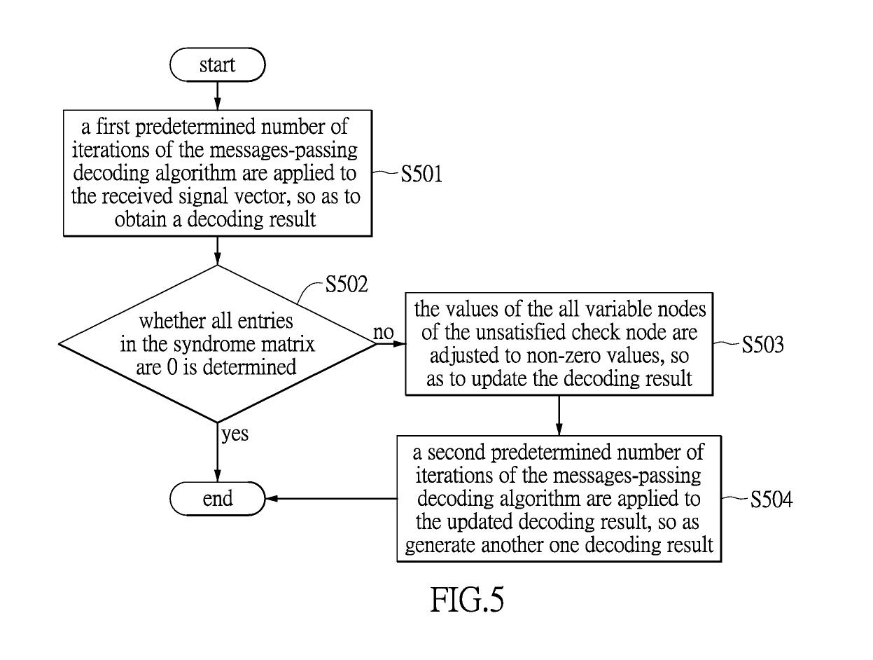

Referring to FIG. 5, FIG. 5 is a flow chart of a decoding method of a LDPC code according to another one exemplary embodiment of the present disclosure. The decoding method of the LDPC code in the exemplary embodiment of FIG. 5 can be executed in the electronic apparatus, and the electronic apparatus has one or more circuits for achieving calculation and storage. In addition, the decoding method of the LDPC code of the exemplary embodiment in FIG. 5 does not need the table.

In FIG. 5, steps S501, S502, S504 are the same as steps S201, S202, 206, and thus the redundant descriptions are omitted. Next, at step S503, the values of the all variable nodes of the unsatisfied check node are adjusted to non-zero values, so as to update the decoding result. For example, the values of the all variable nodes of the unsatisfied check node are assigned to non-zero values, or multiplied by non-zero values, such that the decoding result is updated.

Referring to FIG. 1 and FIG. 5, the (4, 2) trapping set 1 in FIG. 1 can be a dominant trapping set for example. The decoding method of the LDPC code in the exemplary embodiment of FIG. 5 does not use the table to record the location information of the check nodes 101 through 107, variable nodes 111 through 114, 121 through 12M, and 131 through 13N. If at step S502, one of the entries of the syndrome matrix is not 0, then at step S503, the values of the variable nodes 111, 112, 121 through 12M, 131 through 13N are adjusted to non-zero values.

In short, the decoding method of the LDPC code in the exemplary embodiment of FIG. 5, and the values of the variable nodes neighboring to the unsatisfied check node are adjusted at one time. Thus, the decoding method of the LDPC code of the exemplary embodiment in FIG. 5 can reduce the storage space and have the fast decoding speed.

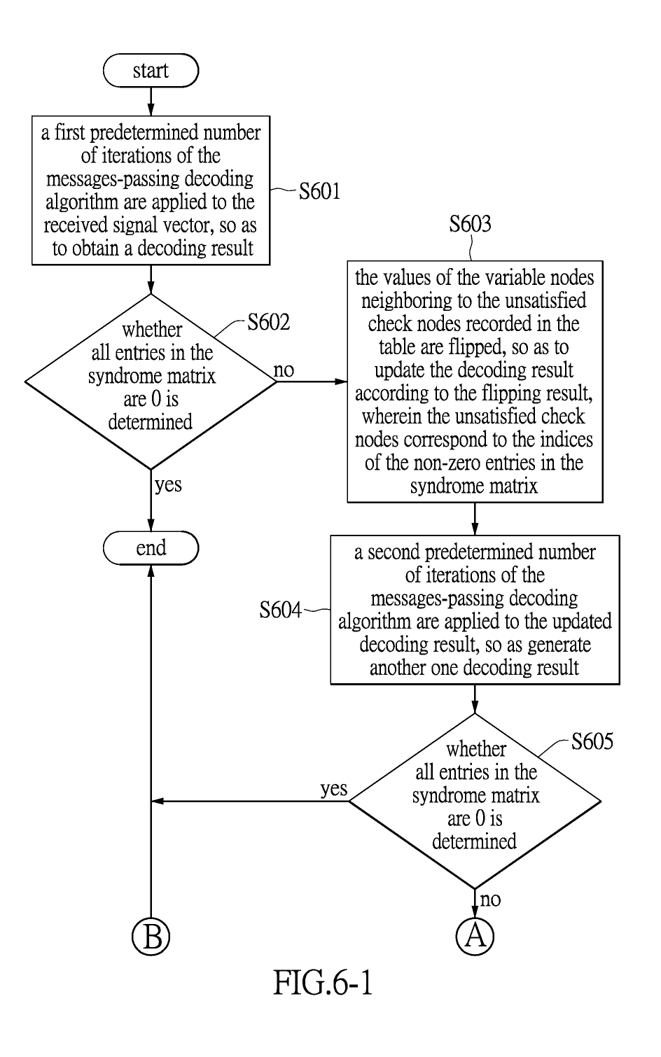

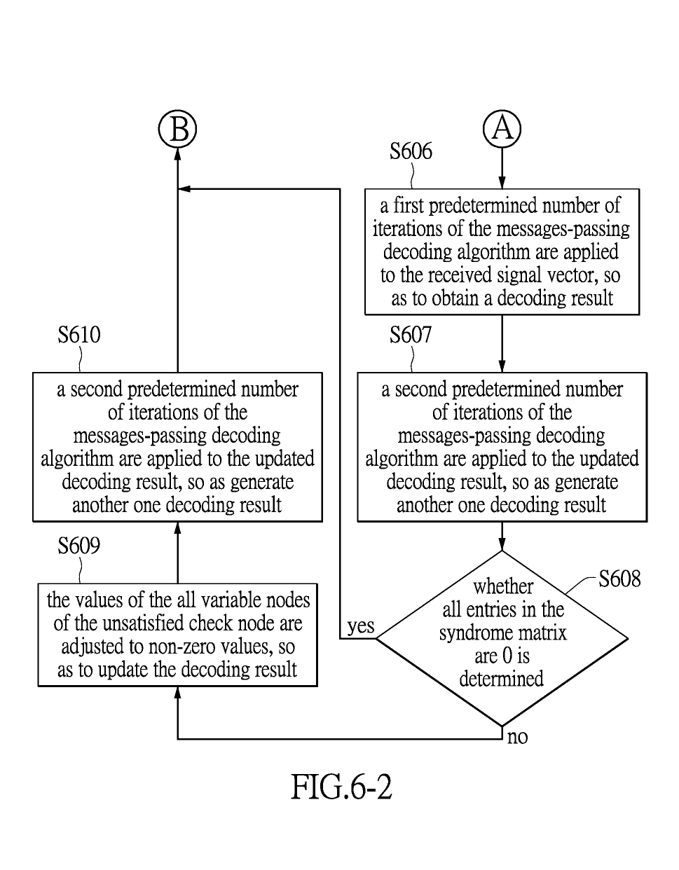

Referring to FIG. 6-1 and FIG. 6-2, FIG. 6-1 and FIG. 6-2 are a flow chart of a decoding method of a LDPC code according to another one exemplary embodiment of the present disclosure. The decoding methods of the LDPC code in the exemplary embodiments of FIG. 2, FIG. 3, and FIG. 5 can be merged or combined, so as to increase the decoding accuracy or decoding speed. In the exemplary embodiment of FIG. 6-1 and FIG. 6-2, step S601 is the same as step S201 in FIG. 2, steps S602, S605, and S608 are the same as step S202 in FIG. 2, steps S603, S606, and S609 are respectively the same as step S205 in FIG. 2, step S303 in FIG. 3, step S503 in FIG. 5, and steps S604, S607, and S610 are the same as step S206 in FIG. 2.

In short, the decoding method of the LDPC code in the exemplary embodiment in FIG. 6-1 and FIG. 6-2 sequentially uses steps of updating values of the variable nodes neighboring to the unsatisfied check node in FIG. 2, FIG. 3, and FIG. 5, so as to increase the decoding accuracy. It is noted that, the present disclosure does not limit the execution order of steps S603, S606, S609 in FIG. 6-1 and FIG. 6-2, and that is, steps S603, S606, and S609 can be exchanged.

Additionally, for the quasi-cyclic LDPC code and other structural LDPC code, an exemplary embodiment of the present disclosure provides an information storing method used in the decoding method of the LDPC code, and by utilizing isomorphism of the structural LDPC code, the necessary storage space for recording information used to resists the error-flooring phenomenon can be reduced. The parity check matrix H of the quasi-cyclic LDPC code can be obtained by extending an z×z (z columns and z rows) unit matrix according to the base matrix QCbase, and the entries of the base matrix QCbase are −1 or positive integers x. If the value of the entry is −1, it means the sub-matrix corresponding to the entry location in the parity check matrix H is a z×z zero matrix. If the value of the entry is x, it means the sub-matrix corresponding to the entry location in the parity check matrix H is a z×z cyclic matrix generated by cyclically right shifting the z×z unit matrix x times.

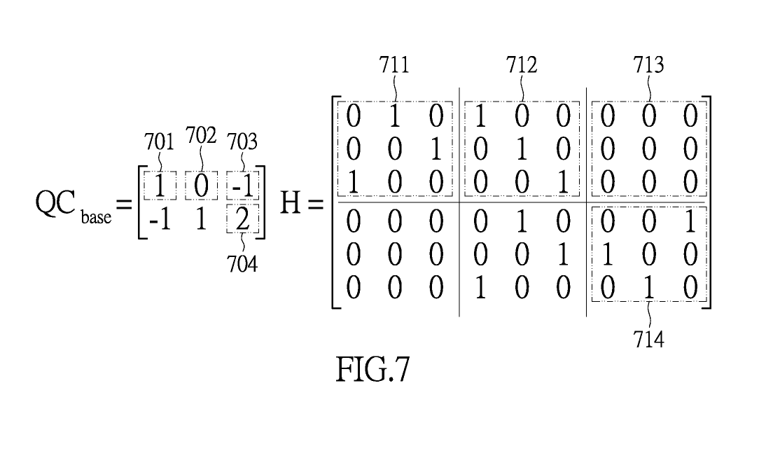

Referring to FIG. 7, FIG. 7 is a schematic diagram of a parity check matrix and a base matrix of a quasi-cyclic LDPC code according to an exemplary embodiment of the present disclosure. In FIG. 7, z is assumed to be 3. Since the value of the entry 701 at first row and first column of the base matrix QCbase is 1, the sub-matrix 711 in the region form by the first through third rows and the first through third columns of the parity check matrix H is a 3×3 cyclic matrix generated by cyclically right shifting the 3×3 unit matrix once. Since the value of the entry 702 at first row and second column of the base matrix QCbase is 0, the sub-matrix 712 in the region form by the first through third rows and the fourth through sixth columns of the parity check matrix H is the 3×3 unit matrix. Since the value of the entry 703 at first row and third column of the base matrix QCbase is −1, the sub-matrix 713 in the region form by the first through third rows and the seventh through ninth columns of the parity check matrix H is the 3×3 zero matrix. Since the value of the entry 704 at second row and first column of the base matrix QCbase is 2, the sub-matrix 714 in the region form by the fourth through sixth rows and the first through third columns of the parity check matrix H is a 3×3 cyclic matrix generated by cyclically right shifting the 3×3 unit matrix twice.

Since the structural LDPC code has isomorphism, and thus if one trapping set has error bits in the specific columns of the sub-matrix and has unsatisfied check nodes in the specific rows of the sub-matrix, z−1 isomorphism trapping sets obviously exist. In other words, the z isomorphism trapping sets can be generated by one isomorphism trapping set and a base matrix QCbase, and that is, merely the information of one isomorphism trapping set and the base matrix QCbase should be recorded, and thus the storage space is reduced much.

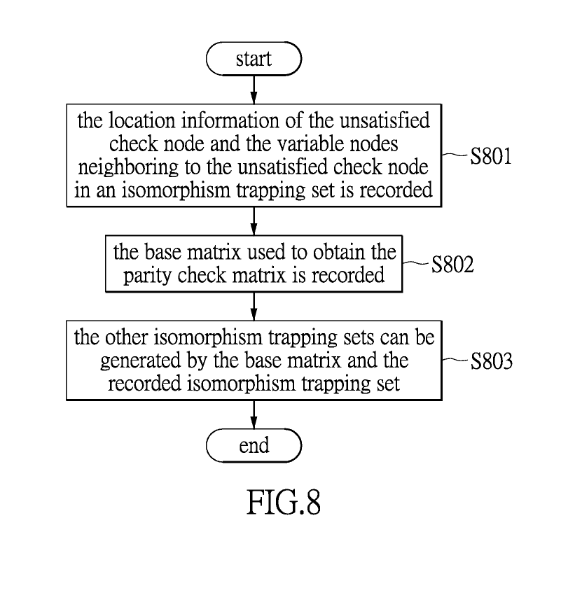

Referring to FIG. 8, FIG. 8 is a flow chart of an information storing method used in a decoding method of a LDPC code according to an exemplary embodiment of the present disclosure. The information storing method in the exemplary embodiment of FIG. 8 can be executed in the electronic apparatus, and the LDPC code should be the structural LDPC code, such as quasi-cyclic LDPC code, and the present disclosure does not limit the structural LDPC code of any type.

Firstly, before the electronic apparatus starts to decode, at step S801, the location information of the unsatisfied check node and the variable nodes neighboring to the unsatisfied check node in an isomorphism trapping set is recorded. Then, at step S802, the base matrix used to obtain the parity check matrix is recorded. Next, when the electronic apparatus receives a codeword not converging to the valid codeword, at step S803, the other isomorphism trapping sets can be generated by the base matrix and the recorded isomorphism trapping set. Next, the electronic apparatus can adjust the values of portion or all of the variable nodes neighboring to the unsatisfied check node, so as to update the decoding result, so as to decode the updated decoding result.

It is noted that, if the LDPC codes in the exemplary embodiments of FIG. 2 and FIG. 3 are structural LDPC codes, for the trapping sets having same structures (i.e. isomorphism trapping sets), the table merely records one of the trapping sets having the same structures, and other trapping sets having the same structures can be generated according to the base matrix and the recorded isomorphism trapping set, wherein the number of the trapping sets needed to be recorded by the table is the same as a category number of the all trapping sets, which is far less than a total number of the all trapping sets, and incorporating with the base matrix recorded by a decoder, the table equivalently records the all trapping sets.

Accordingly, the decoding methods of the LDPC code in the exemplary embodiments of the present disclosure can decrease the storage space and hardware cost. Furthermore, the information storing method used in the decoding method of the LDPC code in the exemplary embodiment of the present disclosure utilizes isomorphism of the structural LDPC code to reduce the necessary storage space for recording information used to resists the error-flooring phenomenon.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A decoding method of a LDPC code, executed in an electronic apparatus, comprising:
step A: applying a first predetermined number of iterations of a messages-passing decoding algorithm to a received signal vector, so as to obtain as decoding result;
step B: determining whether the decoding result converges to a valid codeword;
step C: if the decoding result does not converge to the valid codeword, executing at least one of steps C1 and C2:
the step C1: adjusting values of at least one of variable nodes neighboring to at least one of unsatisfied check nodes to a non-zero value, so as to update the decoding result; and
the step C2: flipping the values of the variable nodes corresponding to the unsatisfied check nodes of trapping sets recorded in a first table, so as to update the decoding result, wherein the first table merely records location information of the unsatisfied check nodes in the trapping sets and location information of merely one of the variable nodes neighboring to the unsatisfied check nodes in the trapping sets; and
step D: applying a second predetermined number of the iterations of the messages-passing decoding algorithm to the updated decoding result, so as to obtain a new decoding result.

2. The decoding method of the LDPC code according to claim 1, wherein at the step C1, the values of the all variable nodes neighboring to the unsatisfied check node in the trapping set are adjusted to non-zero values, so as to update the decoding result.

3. The decoding method of the LDPC code according to claim 1, wherein a second table records the location information of the unsatisfied check nodes in the trapping sets and the location information of the all variable nodes neighboring to the unsatisfied check nodes in the trapping sets, and further records the category information of the recorded variable nodes; and at step C, according to the category information of the recorded variable nodes, the values of the variable nodes are adjusted, so as to update the decoding result.

4. The decoding method of the LDPC code according to claim 3, wherein according to the category information of the recorded variable nodes, the recorded variable nodes are divided to a set of critical variable nodes, a set of common variable node, and a set of negligible variable nodes. Each variable node must be grouped in one of these three sets. The values of the critical variable nodes are adjusted to a first parameter, the values of the common variable nodes are adjusted to a second parameter, and the values of the negligible variable nodes are not adjusted.

5. The decoding method of the LDPC code according to claim 4, wherein the category information, the first parameter, and the second parameter are determined by a simulation result.

6. The decoding method of the LDPC code according to claim 1, wherein when the LDPC code is a structural LDPC code, the structural LDPC code is presented by a base matrix, and portion of the trapping sets have same structures; for the trapping sets having the same structures, the first table merely records one of the trapping sets, and the other trapping sets with the same structures are generated through the base matrix and the recorded isomorphism trapping set, wherein the number of the trapping sets needed to be recorded by the first table is the same as a category number of the all trapping sets, which is far less than a total number of the all trapping sets, and incorporating with the base matrix recorded by a decoder, the first table equivalently records the all trapping sets.

7. The decoding method of the LDPC code according to claim 3, wherein when the LDPC code is a structural LDPC code, the structural LDPC code is presented by a base matrix, and portion of the trapping sets have same structures; for the trapping sets having the same structures, the second table merely records one of the trapping sets, and the other trapping sets with the same structures are generated through the base matrix and the recorded isomorphism trapping set, wherein the number of the trapping sets needed to be recorded by the second table is the same as a category number of the all trapping sets, which is far less than a total number of the all trapping sets, and incorporating with the base matrix recorded by a decoder, the second table equivalently records the all trapping sets.

8. The decoding method of the LDPC code according to claim 3, wherein the first predetermined number is not the same as the second predetermined number.

9. An information storing method using in a decoding method of a LDPC code, executed in an electronic apparatus, adopted for decoding a structural LDPC code, and the information storing method comprises:
step A: recording location information of at least one variable node neighboring to at least one unsatisfied check node in an isomorphism trapping set; and
step B: recording a base matrix for generating a parity check matrix;
wherein the other isomorphism trapping sets can be generated by the base matrix and the recorded isomorphism trapping set.
